(19) United States
(12) Patent Application Publication
(10) Pub. No.: US 2018/0025769 A1
(43) Pub. Date: Jan. 25, 2018

(54) REFRESH CONTROL CIRCUIT AND MEMORY DEVICE INCLUDING THE SAME

(71) Applicant: SK hynix Inc., Icheon-si Gyeonggi-do (KR)

(72) Inventor: Dong Uk LEE, Seoul (KR)

(21) Appl. No.: 15/342,436

(22) Filed: Nov. 3, 2016

(30) Foreign Application Priority Data
Jul. 22, 2016 (KR) 10-2016-0093504

(51) Int. Cl. G11C 11/406; G11C 11/4093; G11C 11/408

(52) U.S. Cl. CPC G11C 11/40611; G11C 11/408; G11C 11/4093

(57) ABSTRACT

A refresh control circuit may be provided. The refresh control circuit may include a row address control circuit configured to reset a corresponding block control signal among a plurality of block control signals, based on a stop signal for stopping a refresh operation of a specific block being enabled. The refresh control circuit may include a refresh enable control circuit configured to combine the plurality of block control signals and a plurality of refresh control signals, and output a refresh enable signal.

### CROSS-REFERENCES TO RELATED APPLICATION

The present application claims priority under 35 U.S.C. §119(a) to Korean application number 10-2016-0093504, filed on Jul. 22, 2016, in the Korean Intellectual Property Office, which is incorporated herein by reference in its entirety.

### BACKGROUND

### 1. Technical Field

Various embodiments may generally relate to a refresh control circuit and a memory device including the same, and more particularly, to a technique capable of reducing a refresh current of a memory device.

### 2. Related Art

Recently, more and more mobile electronic products including smart phones have required large-capacity DRAM. In general, data stored in a memory cell of a semiconductor memory device such as DRAM may be changed by leakage current. Thus, in order to periodically recharge the memory cell, a refresh operation is required.

That is, a memory cell of a dynamic semiconductor memory such as DRAM stores data in a capacitive element. Due to charge leakage from the capacitive element, the memory cell must be periodically refreshed. The refresh process typically includes a step of performing a read operation to fetch the charge level stored in the memory cell as the original state.

In particular, a semiconductor memory device including DDR SDRAM (Double Data Rate Synchronous DRAM) has a plurality of memory banks for storing data, and each of the memory banks has tens of millions or more of memory cells. Each of the memory cells includes a cell capacitor and a cell transistor, and the semiconductor memory device stores data through an operation of charging or discharging the cell capacitor.

Ideally, the electric charge stored in the cell capacitor must be constant at all times, as long as the cell capacitor is not separately controlled. Substantially, however, the electric charge stored in the cell capacitor is changed due to a voltage difference from a peripheral circuit.

That is, electric charge may be leaked in a state where the cell capacitor is charged, or electric charge may be introduced in a state where the cell capacitor is discharged. When the electric charge of the cell capacitor is changed, it may indicate that the data stored in the cell capacitor is changed or lost. The semiconductor memory device performs a refresh operation in order to prevent this type of a data loss.

As time elapses, different types of refresh methods have been developed. According to a normal auto-refresh method, a refresh timer exists outside a memory chip, and the memory chip performs a refresh operation in response to a periodic refresh command supplied by a controller.

Furthermore, according to a self-refresh method, a refresh timer exists in a memory chip, and all memory chips request a refresh start command from a controller.

### SUMMARY

In an embodiment of the present disclosure, a memory device may be provided. In an embodiment of the present disclosure, a refresh control circuit may be provided. The refresh control circuit may include a row address control circuit configured to reset a corresponding block control signal among a plurality of block control signals, based on a stop signal for stopping a refresh operation of a specific block being enabled. The refresh control circuit may include a refresh enable control circuit configured to combine the plurality of block control signals and a plurality of refresh control signals, and output a refresh enable signal.

### BRIEF DESCRIPTION OF THE DRAWINGS

FIG. 1 is a diagram for describing a refresh operation of a memory device.

FIG. 2 is a diagram for describing a refresh operation of a memory device according to an embodiment.

FIG. 3 is a configuration diagram of a representation of an example of the memory device according to an embodiment.

FIG. 4 is a circuit diagram of a representation of an example of a latch circuit of FIG. 3.

FIG. 5 is a timing diagram for describing the operation of the memory device according to an embodiment.

FIG. 6 illustrates a block diagram of an example of a representation of a system employing a memory device and or refresh control circuit with the various embodiments discussed above with relation to FIGS. 1-5.

### DETAILED DESCRIPTION

Hereinafter, a refresh control circuit and a memory device including the same according to the present disclosure will be described below with reference to the accompanying drawings through examples of embodiments.

Various embodiments may be directed to a refresh control circuit capable of reducing a refresh current by performing a refresh operation only on a region where a program is used, and a memory device including the same.

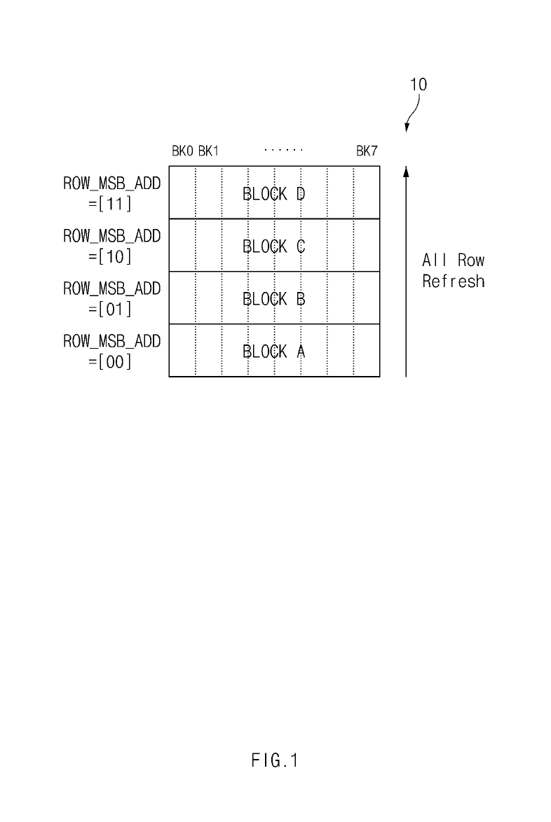

FIG. 1 is a diagram for describing a refresh operation of a memory device.

The memory device may have a memory region 10 including a plurality of banks BK0 to BK7. The plurality of banks BK0 to BK7 may have row lines which are divided into a plurality of blocks A to D according to a row address.

The plurality of blocks A to D may be divided according to the MSB (Most Significant Bit) of the row address. For example, when the MSB address ROW_MSB_ADD is “00”, it may indicate the block A. When the MSB address ROW_MSB_ADD is “01”, it may indicate the block B. When the MSB address ROW_MSB_ADD is “10”, it may indicate the block C. When the MSB address ROW_MSB_ADD is “11”, it may indicate the block D.

The memory region 10 may be used or not used for each of the blocks A to D. Although there exists an unused block among the blocks A to D, refresh operations are sequentially performed on all of the blocks A to D. When an unused block is refreshed, a refresh operation current is increased.

In a memory device (for example, DRAM), a standby current and operating current are consumed by a refresh operation. Furthermore, the consumption of the refresh current increases in proportion to the density of a memory. In particular, a mobile system having a high-density memory mounted therein exhibits a memory usage rate which is changed depending on the actual use of applications. However, when the refresh operation current is determined according to the density of the memory regardless of whether the memory is used, the standby current may increase in proportion to the density of the memory mounted in the memory device.

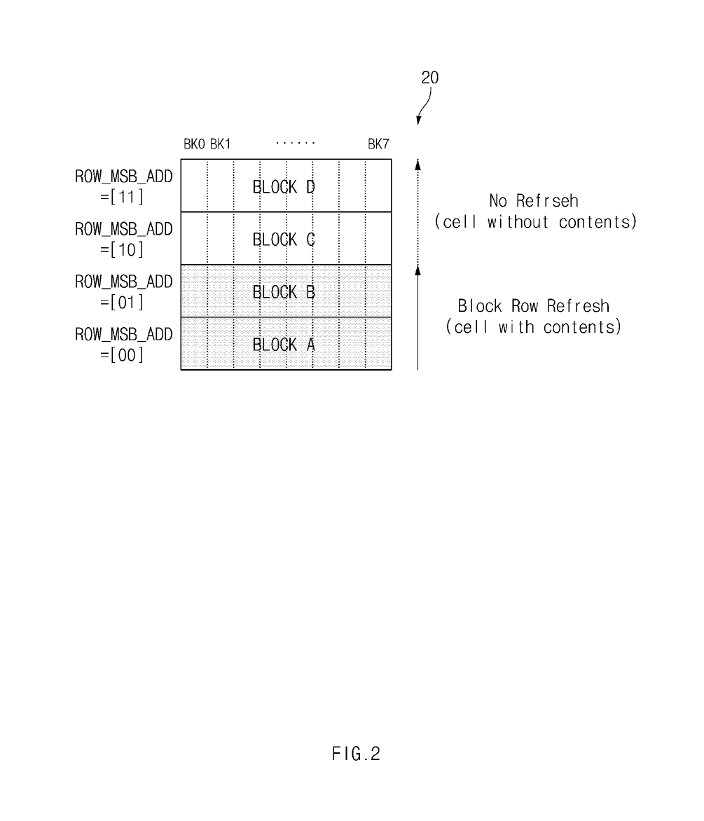

FIG. 2 is a diagram for describing the refresh operation of the memory device according to an embodiment.

The memory device may have a memory region 20 including a plurality of banks BK0 to BK7. The plurality of banks BK0 to BK7 may include row lines which are divided into a plurality of blocks A to D according to a row address.

The plurality of blocks A to D may be divided according to the MSB (Most Significant Bit) of the row address. For example, when the MSB address ROW_MSB_ADD is “00”, it may indicate the block A. When the MSB address ROW_MSB_ADD is “01”, it may indicate the block B. When the MSB address ROW_MSB_ADD is “10”, it may indicate the block C. When the MSB address ROW_MSB_ADD is “11”, it may indicate the block D.

In a present embodiment, the memory device includes the eight banks BK0 to BK7 which are divided into the four blocks A to D. However, present embodiments are not limited thereto, but the number of banks can be changed according to the number of row addresses.

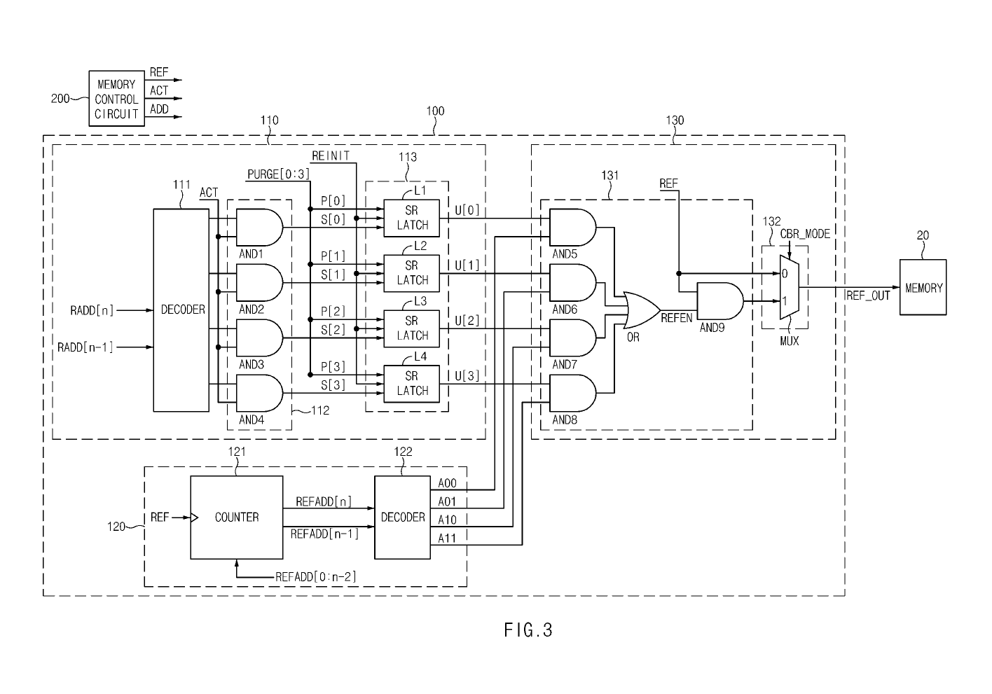

The blocks A to D of the memory region 20 may be controlled by a memory control circuit 200 (see FIG. 3). The memory control circuit 200 may be a program having a function of managing a memory resource. Through this program, the OS (Operating System) manages a memory region for each program.

That is, the memory control circuit 200 includes a program ID field, a virtual address field and a physical address field. The memory control circuit 200 manages the memory region 20 by operating a table for mapping a program ID, a virtual address and a physical address.

The physical address may have a specific region of bits mapped to a row address of the memory region 20. The bit information of the specific region in the physical address may be set to row refresh information of the memory region 20, in order to control a refresh operation of the memory region 20.

The memory region 20 may skip a refresh operation for an unused region, in response to an address ADD, a refresh signal REF and an active signal ACT which are applied from the memory control circuit 200. That is, the system dynamically allocates a memory region when a program is generated, and removes the allocation of the memory region when the program disappears.

For example, since the blocks A and B of the entire memory are used by the program according to an application, a row refresh operation is performed only on the blocks A and B with contents. On the other hand, since the blocks C and D are not used by the program, a row refresh operation is not performed on the blocks C and D.

As the memory capacity of a computing system is raised, a current for operating the memory is increased. In particular, since DRAM uses a refresh current proportional to a memory capacity, a refresh current of a memory may become the most serious issue in future high-capacity memory computing systems.

Basically, a memory system refreshes all memory cell arrays. However, the memory system refreshes all memory cells regardless of whether a corresponding region is used. Thus, when the number of refresh operations for unused regions is reduced, the current consumption can be reduced while the reliability of the system is maintained.

In the memory system, the memory control circuit 200 manages information on whether the physical addresses of the memory cells are actually used. The OS includes a program for operating the memory control circuit 200. Through the program, the limited physical memory region can be controlled to be used by a plurality of programs. Thus, a user can determine which physical address region is a used region or discarded region, through the OS program.

As described above, the memory device according to a present embodiment distinguishes between a region which uses a program and a region which does not use a program in the system, through a physical address. A command decoder of the memory device receives information on a row address which uses a program and a row address which does not use a program.

Since the cells of the memory device (for example, DRAM) have a data retention time, the cells need to be periodically refreshed in order to prevent a data loss. As the density of DRAM is increased, the number of cells to be refreshed is also increased. In this case, the refresh current is increased, and the consumption of standby power used for the self-refresh operation is increased.

In a present embodiment, a region which does not use a program may skip the refresh operation of the memory region 20. Furthermore, only an actually used region may be controlled to be refreshed, in order to reduce the refresh current of the memory device. Moreover, when the usage rate of the memory is low regardless of the density of the memory, the standby power consumed by the refresh operation can be reduced.

FIG. 3 is a configuration diagram of a representation of an example of a memory device according to an embodiment.

The memory device according to a present embodiment includes a memory 20 and a refresh control circuit 100. The refresh control circuit 100 includes a row address control circuit 110, a refresh address control circuit 120 and a refresh enable control circuit 130.

The row address control circuit 110 includes a decoder 111, an active control circuit 112 and a latch circuit 113. The row address control circuit 110 latches a row address RADD[n] and RADD[n−1] in response to an active signal ACT, a reinitialization signal REINIT and a stop signal PURGE[0:3], and outputs a block control signal U[0:3].

The row address control circuit 110 determines whether a memory block is used, according to the active signal ACT and the row address RADD[n] and RADD[n−1] corresponding to the MSB. When a specific row address is activated, a refresh operation is performed on a block basis under the supposition that the entire block is used by the row address RADD[n] and RADD[n−1] corresponding to the MSB.

The decoder 111 decodes the row address RADD[n] and RADD[n−1], and outputs the decoded address to the active control circuit 112. The decoder 111 may decode the MSB of the row address.

For example, the decoder 111 may decode the two MSBs of the row address. When the memory region 20 is divided into the four blocks A to D as illustrated in FIG. 2, the decoder 111 may decode the two MSBs. The decoder 111 decodes the n-th bit and (n−1)th bit of the row address, that is, the MSB RADD[n] and the MSB RADD[n−1].

The active control circuit 112 combines an output of the decoder 111 and the active signal ACT, and outputs a control signal S[0:3] to the latch circuit 113. The active control circuit 112 enables the control signal S[0:3] when both the output of the decoder 111 and the active signal ACT are enabled. The active control circuit 112 includes a plurality of AND gates AND1 to AND4 which perform an AND operation on the output of the decoder 111 and the active signal ACT and output the operation result as the control signal S[0:3].

When the active signal ACT is enabled, the logic level of the control signal S[0:3] is changed according to the decoding result of the row address RADD[n] and RADD[n−1]. That is, when the active signal ACT is enabled, information on whether the respective memory blocks are used is stored in the latch circuit 113, in response to the control signal S[0:3].

The latch circuit 113 latches the reinitialization signal REINIT, the stop signal PURGE[0:3] and the control signal S[0:3], and outputs the block control signal U[0:3]. The latch circuit 113 includes a plurality of SR latches L1 to L4 for latching the reinitialization signal REINIT, the stop signal PURGE[0:3] and the control signal S[0:3].

The SR latch L1 latches the reinitialization signal REINIT, the stop signal PURGE[0] and the control signal S[0], and outputs the block control signal U[0]. The SR latch L2 latches the reinitialization signal REINIT, the stop signal PURGE[1] and the control signal S[1], and outputs the block control signal U[1]. The SR latch L3 latches the reinitialization signal REINIT, the stop signal PURGE[2] and the control signal S[2], and outputs the block control signal U[2]. The SR latch L4 latches the reinitialization signal REINIT, the stop signal PURGE[3] and the control signal S[3], and outputs the block control signal U[3].

The reinitialization signal REINIT is enabled in a boot-up state. The latch circuit 113 disables the block control signal U[0:3] when the reinitialization signal REINIT is enabled. When the block control signal U[0:3] is disabled, a refresh enable signal REFEN is disabled. That is, when the reinitialization signal REINIT is enabled during a boot-up operation, an output of the combination circuit 131 is disabled. Then, a refresh output signal REF_OUT is disabled, and a refresh operation is not performed.

The stop signal PURGE[0:3] is used to stop a refresh operation on an unused memory block which is designated by a user. When the corresponding bit PURGE[0] of the stop signal PURGE[0:3] is enabled, the SR latch L1 is reset. Then, a refresh operation for the corresponding memory block is not performed.

The refresh address control circuit 120 outputs refresh control signals A00, A01, A10 and A11 to the refresh enable control circuit 130 in response to the refresh signal REF and a refresh address REFADD[0:n−2].

The refresh address control circuit 120 includes a counter 121 and a decoder 122. The counter 121 counts the refresh address REFADD[0:n−2] according to the refresh signal REF, and outputs a refresh address REFADD[n−1] and REFADD[n]. The refresh signal REF may be generated by the memory control circuit 200. The row address RADD[0:n] may correspond to an address ADD applied from the memory control circuit 200.

Whenever the refresh signal REF is generated, the refresh address REFADD[0:n−2] is increased. When the output of the counter 121 is increased to the refresh address REFADD[n−1] and REFADD[n], the refresh address REFADD[n−1] and REFADD[n] is enabled.

The decoder 122 decodes the refresh address REFADD[n−1] and REFADD[n], and outputs the refresh control signals A00, A01, A10 and A11.

The refresh address REFADD[0:n−2] corresponding to low-order bits of the refresh address REFADD[0:n] may be used to select a row line on which a refresh operation is to be performed. The refresh address REFADD[n−1] and REFADD[n] corresponding to the two MSBs of the refresh address REFADD[0:n] may be used to select a block on which a refresh operation is to be performed, between the blocks A and B.

The refresh enable control circuit 130 includes a combination circuit 131 and a selection circuit 132. The refresh enable control circuit 130 generates the refresh enable signal REFEN by combining an output signal of the row address control circuit 110, an output signal of the refresh address control circuit 120 and the refresh signal REF.

The combination circuit 131 includes a plurality of AND gates AND5 to AND9 and an OR gate OR. The AND gate AND5 performs an AND operation on the block control signal U[0] and the refresh control signal A00. The AND gate AND6 performs an AND operation on the block control signal U[1] and the refresh control signal A01. The AND gate AND7 performs an AND operation on the block control signal U[2] and the refresh control signal A10. The AND gate AND8 performs an AND operation on the block control signal U[3] and the refresh control signal A11.

The OR gate OR performs an OR operation on outputs of the plurality of AND gate AND5 to AND9, and outputs the refresh enable signal REFEN. The refresh enable control circuit 130 enables the refresh enable signal REFEN when at least any one of the outputs of the AND gates AND5 to AND9 is enabled.

The AND gate AND9 performs an AND operation on the refresh signal REF and the refresh enable signal REFEN. That is, the AND gate AND9 enables and outputs the refresh enable signal REFEN at an active period of the refresh signal REF.

As such, the combination circuit 131 enables the refresh enable signal REFEN when both of the block control signal U[0] and the refresh control signal A00 are enabled, both of the block control signal U[1] and the refresh control signal A01 are enabled, both of the block control signal U[2] and the refresh control signal A10 are enabled, or both of the block control signal U[3] and the refresh control signal A11 are enabled.

The selection circuit 132 selects any one of the refresh signal REF and the output of the AND gate AND9 in response to a mode signal CBR_MODE, and outputs the selected signal as the refresh output signal REF_OUT. The selection circuit 132 includes a multiplexer MUX.

The multiplexer MUX selects the refresh signal REF when the mode signal CBR_MODE is at a low level, and selects the output signal of the AND gate AND9 when the mode signal CBR_MODE is at a high level. The mode signal CBR_MODE is a signal for controlling an output pulse of a refresh operation according to a CBR (CAS before RAS) signal.

The memory control circuit 200 may transmit an auto-refresh command through a row active-precharge operation instruction during a normal operation, without providing a separate auto-refresh command to a memory. This method is referred to as a hidden auto-refresh method.

According to the hidden auto-refresh method, a separate auto-refresh command having an operation period distinguished from a normal operation period is not provided, but a row active-precharge operation is instructed within the normal operation period. Therefore, the hidden auto-refresh method can increase the time during which the memory can be accessed.

At this time, the row active-precharge operation according to the hidden auto-refresh method uses the CBR (CAS Before RAS) method. That is, as a CAS (Column Access Strobe) signal is enabled before a RAS (Row Access Strobe) signal, the memory can distinguish between the hidden auto-refresh operation and the normal active-precharge operation.

In a present embodiment, when the mode signal CBR_MODE is at a logic low level, the refresh signal REF is outputted as the refresh output signal REF_OUT such that a refresh operation is performed according to the CBR method. On the other hand, when the mode signal CBR_MODE is at a logic high level, the refresh enable signal REFEN is outputted as the refresh output signal REF_OUT such that a refresh operation is performed on each of blocks with contents. Further, the logic levels of the signals may be different from or the opposite of those described. For example, a signal described as having a logic “high” level may alternatively have a logic “low” level, and a signal described as having a logic “low” level may alternatively have a logic “high” level.

In the memory 20, a refresh operation is performed on each of the blocks A to D according to the refresh output signal REF_OUT. As illustrated in FIG. 2, the banks BK0 to BK7 of the memory 20 may be divided into the blocks A to D.

In the cell array of the memory 20, a read operation, write operation, precharge operation or refresh operation for data is performed in a cell selected in response to decoding signals of a row decoder and a column decoder. Furthermore, as a row line of the cell array is selected by the refresh output signal REF_OUT, a refresh operation of the memory 20 is performed.

That is, when the refresh output signal REF_OUT is at a low level, it may indicate that the corresponding memory region of the memory 20 is disabled. Then, a refresh operation is not performed on the corresponding region. Further, the logic levels of the signals may be different from or the opposite of those described. For example, a signal described as having a logic “high” level may alternatively have a logic “low” level, and a signal described as having a logic “low” level may alternatively have a logic “high” level.

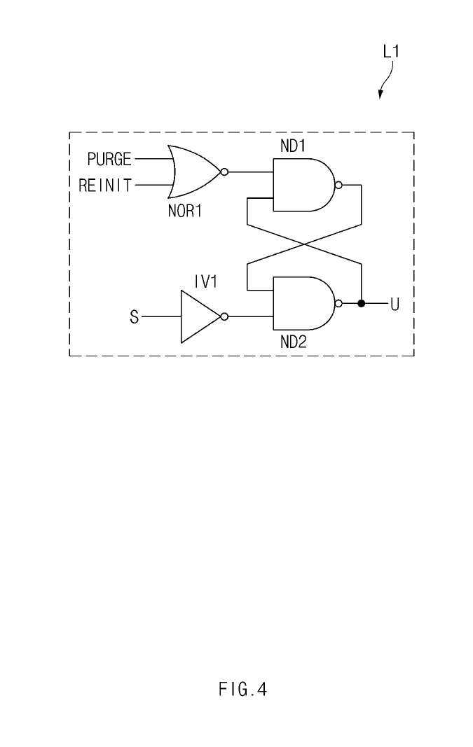

FIG. 4 is a circuit diagram of the SR latch L1 of FIG. 3. Since the SR latches L1 to L4 have the same configuration, the configuration of the SR latch L1 will be representatively described.

The SR latch L1 includes a NOR gate NOR1, an inverter IV1 and a plurality of NAND gates ND1 and ND2. The plurality of NAND gates ND1 and ND2 are coupled to each other through an SR latch structure.

The NOR gate NOR1 performs a NOR operation on the reinitialization signal REINIT and the stop signal PURGE. The NAND gate ND1 performs a NAND operation on an output signal of the NOR gate NOR1 and an output signal of the NAND gate ND2. The NAND gate ND2 performs a NAND operation on an output signal of the NAND gate ND1 and a control signal S inverted by the inverter IV1, and outputs a block control signal U.

The SR latch L1 having such a configuration latches the control signal S and outputs the block control signal U. When at least any one of the reinitialization signal REINIT and the stop signal PURGE is enabled, the SR latch L1 is reset to disable the block control signal U.

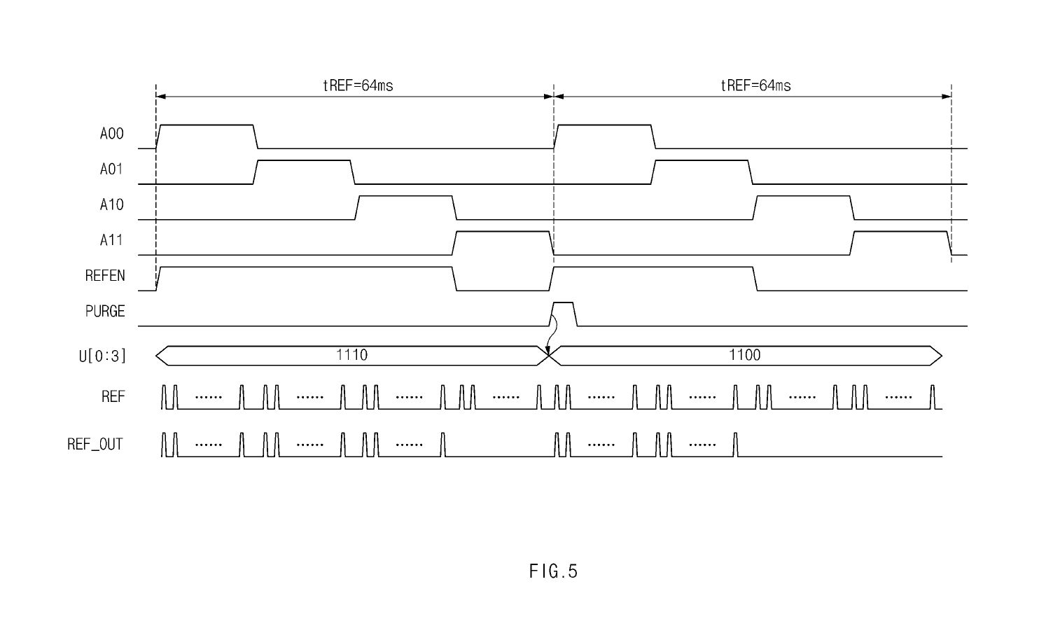

FIG. 5 is a timing diagram for describing the operation of the memory device according to an embodiment.

When the refresh signal REF is applied, the refresh control signals A00, A01, A10 and A11 are sequentially enabled. When the respective bits of the block control signal U[0:3] are “1110”, the combination circuit 131 performs an AND operation on the block control signal U[0:3] and the logic levels of the refresh control signals A00, A01, A10 and A11.

That is, the combination circuit 131 combines the high-level refresh control signals A00, A01 and A10 and the high-level block control signals U[0:2], and outputs the refresh enable signal REFEN at a high level. Then, only during a period in which the refresh control signals A00, A01 and A10 are at a high level, a refresh operation is performed.

Then, when the block control signal U[3] is at a low level even though the refresh control signal A11 is at a high level, the refresh enable signal REFEN is outputted at a low level. Then, only when the refresh enable signal REFEN is enabled at an active period of the refresh signal REF, the refresh output signal REF_OUT is enabled to a high level. On the other hand, when the refresh enable signal REFEN is disabled at an active period of the refresh signal REF, the refresh output signal REF_OUT is disabled.

When the respective bits of the block control signal U[0:3] are “1100”, the combination circuit 131 performs an AND operation on the block control signal U[0:3] and the logic levels of the refresh control signals A00, A01, A10 and A11.

That is, the combination circuit 131 combines the high-level refresh control signals A00 and A01 and the high-level block control signals U[0:1], and outputs the refresh enable signal REFEN at a high level. Then, only during a period in which the refresh control signals A00 and A01 are at a high level, a refresh operation is performed.

Then, when the block control signals U[2:3] are at a low level even though the refresh control signals A10 and A11 are at a high level, the refresh enable signal REFEN is outputted at a low level. Then, only when the refresh enable signal REFEN is enabled at an active period of the refresh signal REF, the refresh output signal REF_OUT is enabled at a high level. On the other hand, when the refresh enable signal REFEN is disabled at an active period of the refresh signal REF, the refresh output signal REF_OUT is disabled.

At this time, the block control signal U[0:3] is reset at a period in which the stop signal PURGE is enabled. For example, when the stop signal PURGE[2] is enabled, the third bit of the block signal U[0:3] is reset to “0”. Thus, the block control signal U[0:3] is changed from “1110” to “1100”.

For example, the block control signal U[0] may be matched with the refresh operation of the block A in FIG. 2, and the block control signal U[1] may be matched with the refresh operation of the block B in FIG. 2. For example, the block control signal U[2] may be matched with the refresh operation of the block C in FIG. 2, and the block control signal U[3] may be matched with the refresh operation of the block D in FIG. 2.

In an embodiment of FIG. 5, the refresh cycle tREF is set to 64 ms. However, the present embodiments are not limited thereto, but the refresh cycle can be changed.

Furthermore, the present embodiments can be applied to a device such as a mobile phone or PC, in which a boot-up operation is periodically performed, and reduce a refresh current according to an actual usage rate. Furthermore, when the present embodiments are applied to a server in which a boot-up operation is not performed for a long term, a refresh operation for an unused memory block may be skipped through a mode register or the like. That is, the stop signal PURGE may be provided on a memory block basis through the mode register or the like, in order to stop the refresh operation.

According to the present embodiments, the refresh control circuit and the memory device can reduce a refresh current by performing a refresh operation only on a region where a program is used in a memory.

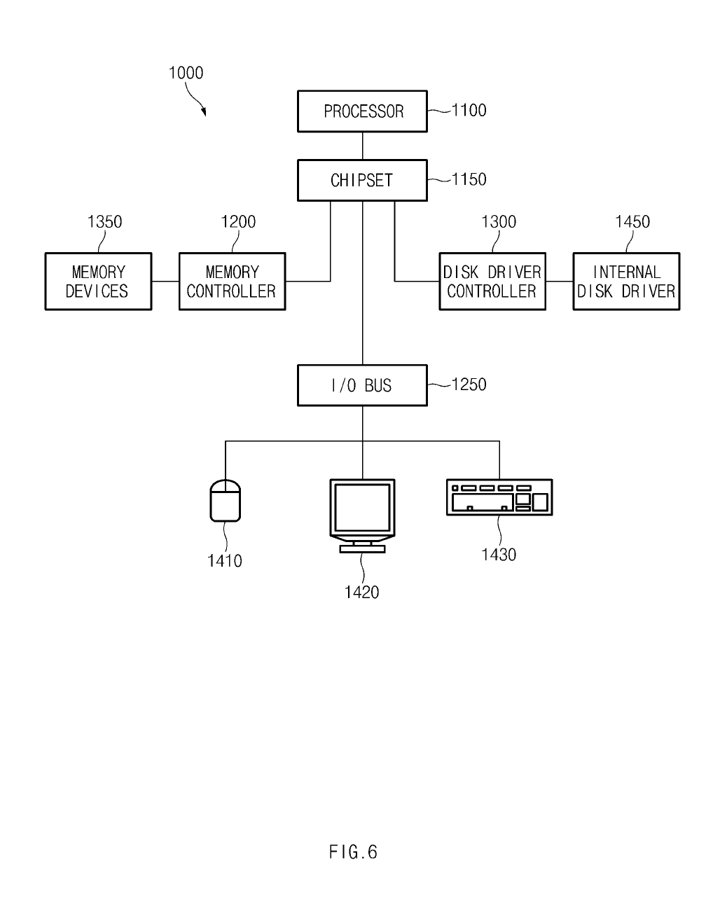

The memory devices and or refresh control circuits as discussed above (see FIGS. 1-5) are particular useful in the design of other memory devices, processors, and computer systems. For example, referring to FIG. 6, a block diagram of a system employing a semiconductor device in accordance with the various embodiments are illustrated and generally designated by a reference numeral 1000. The system 1000 may include one or more processors (i.e., Processor) or, for example but not limited to, central processing units (“CPUs”) 1100. The processor (i.e., CPU) 1100 may be used individually or in combination with other processors (i.e., CPUs). While the processor (i.e., CPU) 1100 will be referred to primarily in the singular, it will be understood by those skilled in the art that a system 1000 with any number of physical or logical processors (i.e., CPUs) may be implemented.

A chipset 1150 may be operably coupled to the processor (i.e., CPU) 1100. The chipset 1150 is a communication pathway for signals between the processor (i.e., CPU) 1100 and other components of the system 1000. Other components of the system 1000 may include a memory controller 1200, an input/output (“I/O”) bus 1250, and a disk driver controller 1300. Depending on the configuration of the system 1000, any one of a number of different signals may be transmitted through the chipset 1150, and those skilled in the art will appreciate that the routing of the signals throughout the system 1000 can be readily adjusted without changing the underlying nature of the system 1000.

As stated above, the memory controller 1200 may be operably coupled to the chipset 1150. The memory controller 1200 may include at least one memory device and or refresh control circuit as discussed above with reference to FIGS. 1-5. Thus, the memory controller 1200 can receive a request provided from the processor (i.e., CPU) 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the at least one memory device and or refresh control circuit as discussed above with relation to FIGS. 1-5, the memory devices 1350 may include a plurality of word lines and a plurality of bit lines for defining a plurality of memory cells. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420, and 1430. The I/O devices 1410, 1420, and 1430 may include, for example but are not limited to, a mouse 1410, a video display 1420, or a keyboard 1430. The I/O bus 1250 may employ any one of a number of communications protocols to communicate with the I/O devices 1410, 1420, and 1430. In an embodiment, the I/O bus 1250 may be integrated into the chipset 1150.

The disk driver controller 1300 may be operably coupled to the chipset 1150. The disk driver controller 1300 may serve as the communication pathway between the chipset 1150 and one internal disk driver 1450 or more than one internal disk driver 1450. The internal disk driver 1450 may facilitate disconnection of the external data storage devices by storing both instructions and data. The disk driver controller 1300 and the internal disk driver 1450 may communicate with each other or with the chipset 1150 using virtually any type of communication protocol, including, for example but not limited to, all of those mentioned above with regard to the I/O bus 1250.

It is important to note that the system 1000 described above in relation to FIG. 6 is merely one example of a memory device and or refresh control circuit as discussed above with relation to FIGS. 1-5. In alternate embodiments, such as, for example but not limited to, cellular phones or digital cameras, the components may differ from the embodiments illustrated in FIG. 6.

While certain embodiments have been described above, it will be understood to those skilled in the art that the embodiments described are by way of example only. Accordingly, the memory device described herein should not be limited based on the described embodiments. Rather, the memory device described herein should only be limited in light of the claims that follow when taken in conjunction with the above description and accompanying drawings.

What is claimed is:

1. A refresh control circuit comprising:
a row address control circuit configured to reset a corresponding block control signal among a plurality of block control signals, based on a stop signal for stopping a refresh operation of a specific block being enabled; and
a refresh enable control circuit configured to combine the plurality of block control signals and a plurality of refresh control signals, and output a refresh enable signal.

2. The refresh control circuit according to claim 1, wherein the row address control circuit latches a control signal for skipping a refresh operation on an unused memory block based on a specific bit of a row address and an active signal, and outputs the plurality of block control signals which are matched with the memory block.

3. The refresh control circuit according to claim 2, wherein the row address control circuit comprises:
a first decoder configured to decode the specific bit of row address;
an active control circuit configured to output the control signal based on an output of the first decoder and the active signal; and
a latch circuit configured to latch the control signal and output the plurality of block control signals.

4. The refresh control circuit according to claim 3, wherein the latch circuit resets the block control signal based on a reinitialization signal being enabled during a boot-up operation.

5. The refresh control circuit according to claim 3, wherein the active control circuit enables the control signal based on both of the output of the first decoder and the active signal being enabled.

6. The refresh control circuit according to claim 3, wherein the latch circuit comprises a plurality of SR latches of which the number corresponds to the plurality of block control signals.

7. The refresh control circuit according to claim 2, wherein the specific bit of the row address comprises two MSBs (Most Significant Bits).

8. The refresh control circuit according to claim 1, further comprising a refresh address control circuit configured to count and decode a refresh address based on a refresh signal and output the plurality of refresh control signals for controlling a refresh operation of a memory block.

9. The refresh control circuit according to claim 8, wherein the refresh address control circuit comprises:
a counter configured to count the refresh address based on the refresh signal; and
a second decoder configured to decode a specific bit of a refresh address contained in an output of the counter and output the plurality of refresh control signals.

10. The refresh control circuit according to claim 8, wherein the specific bit of the refresh address comprises two MSBs.

11. The refresh control circuit according to claim 1, wherein the plurality of refresh control signals are sequentially enabled.

12. The refresh control circuit according to claim 1, wherein the refresh enable control circuit comprises:
a combination circuit configured to combine the plurality of block control signals and the plurality of refresh control signals; and
a selection circuit configured to select any one of an output of the combination circuit and a refresh signal based on a mode signal, and output the selected signal as a refresh output signal.

13. The refresh control circuit according to claim 12, wherein the combination circuit comprises:
a plurality of logic gates configured to perform an AND operation on the plurality of block control signals and the plurality of refresh control signals; and
a logic gate configured to perform an OR operation on outputs of the plurality of logic gates.

14. The refresh control circuit according to claim 12, wherein the mode signal comprises a signal controlled by a CBR (CAS (column address strobe) Before RAS (row address strobe)) method.

15. A memory device comprising:
a refresh control circuit configured to store row address information for performing a refresh operation only on a region in which a program is performed, based on a specific bit of a row address and an active signal, and output a refresh enable signal for controlling a refresh operation of a memory block by counting a refresh address based on a refresh signal; and
a memory region configured to perform a refresh operation only on a used region corresponding to a row address based on the refresh enable signal.

16. The memory device according to claim 15, wherein the memory region is divided into a plurality of blocks based on the specific bit of the row address, and a refresh operation for each of the blocks is controlled based on whether the program is executed.

17. The memory device according to claim 15, wherein the refresh control circuit comprises:
a row address control circuit configured to latch a control signal for skipping a refresh operation on an unused memory block based on the specific bit of the row address and the active signal, and output a plurality of block control signals which are matched with the memory block;
a refresh address control circuit configured to count and decode the refresh address based on the refresh signal, and output a plurality of refresh control signals for controlling a refresh operation of the memory block; and
a refresh enable control circuit configured to combine the plurality of block control signals and the plurality of refresh control signals, and output the refresh enable signal.

18. The memory device according to claim 17, wherein the row address control circuit comprises:
a first decoder configured to decode the specific bit of the row address;
an active control circuit configured to output the control signal based on an output of the first decoder and the active signal; and
a latch circuit configured to latch the control signal and output the plurality of block control signals.

19. The memory device according to claim 17, wherein the refresh address control circuit comprises:
a counter configured to count the refresh address based on the refresh signal; and
a second decoder configured to decode a specific bit of a refresh address contained in an output of the counter, and output the plurality of refresh control signals.

20. The memory device according to claim 17, wherein the refresh enable control circuit comprises:
a combination circuit configured to combine the plurality of block control signals and the plurality of refresh control signals; and
a selection circuit configured to select any one of an output of the combination circuit and the refresh signal based on a mode signal, and output the selected signal as a refresh output signal.
